(19) United States
(12) Patent Application Publication
(10) Pub. No.: US 2008/0265393 A1
(43) Pub. Date: Oct. 30, 2008

(54) STACK PACKAGE WITH RELEASING LAYER AND METHOD FOR FORMING THE SAME

(75) Inventors: Diann-Fang Lin, Hukou Township (TW); Wen-Kun Yang, Hsin-Chu City (TW)

Correspondence Address: KUSNER & JAFFE;HIGHLAND PLACE SUITE 310, 6151 WILSON MILLS ROAD, HIGHLAND HEIGHTS, OH, 44143, US

(73) Assignee: Advanced Chip Engineering Technology Inc.

(21) Appl. No.: 11/739,241

(22) Filed: Apr. 24, 2007

(51) Int. Cl. H01L 23/48; H01L 21/00

(52) U.S. Cl. 257/690; 438/118; 257/E23.01; 257/E21.001

(57) ABSTRACT

The present invention provides a structure and a of stacked dice package and a process for forming the same, wherein an elastic adhesive layer applied on the first die covering all top surface of the first die and forming rims at the peripheral edges of the first die except the openings formed on the first contacting pads. With this shape of the elastic adhesive layer, the present invention can avoid micro crack happens in the die while performing wire bonding on the contacting pad of the die.

### FIELD OF THE INVENTION

The present invention relates to a structure for stacked package, and more particularly to a stack package with a releasing layer

### DESCRIPTION OF THE PRIOR ART

In the field of semiconductor devices, the device density is increased but the device dimension is reduced. The traditional package technique can't meet the demand of producing smaller chip with high density elements on the chip; therefore, new packaging or interconnecting techniques for such high density devices become demanding.

Performing wire-bonding on a semiconductor package with stacked dice encounters many problems. Wire-bonding equipment induces significant force to the bonding pad on the die during wire-bonding; therefore, micro cracking in the die might happen.

Some inventions have been proposed to solve the problem. U.S. Patent No. 2005/0035461 discloses a multiple stacked dice packaging structure with a n-shaped carrier cap; the n-shaped carrier is provided between the upper and the lower chip for ensuring coplanar when performing wire-bonding on the upper chip. Though the invention provides a cap for supporting the upper die, it needs large spacing which is inadequate for micro devices.

Another solution proposed is adding an adhesive layer between the dice of a stacked dice to provide support for the upper die. U.S. Patent No. 2004/0251526 discloses a semiconductor package with stacked dice. An intermediate adhesive layer is applied between the upper die and the lower die. The adhesive layer provides support for the upper die while performing wire-bonding thereby reducing the incidence of die cracking; therefore, the invention discloses a structure and a method increase the yield of stacked packaging. The shortcoming of this invention is that the adhesive layer is injected by adhesive application equipment such as nozzle; unfortunately, the injection force is too strong to maintain bonding wire on the bonding point; i.e., the contacting point of wire binding on the pads may be damaged. As shown in FIG. 1, another shortcoming of injecting an adhesion layer includes that the adhesion layer can't cover the top surface of the pads thoroughly and the elastic particles in the adhesion layer can't spread evenly also.

Therefore, the present invention provides a stacked structure with a releasing layer to solve the problem of micro cracking in the die.

### SUMMARY OF THE INVENTION

One advantage of the present invention is providing a method for coating an elastic adhesion material on a die and forming an opening on contacting pads before performing wire-bonding.

Another advantage of the present invention is providing an upper chip without adhesive on its backside,

Still another advantage of the present invention is providing a structure and a method without causing micro-cracking in the chip while performing wire-bonding.

The present invention provides a structure of stacked dice package, comprising: a substrate with pluralities of pads; a first die with a first contacting pad attached on the substrate; a first wire electrically connected the pad and the first contacting pad; an elastic adhesive layer applied on the die, wherein the elastic adhesive layer covering all top surface of the first die and forming rims at the peripheral edges of the first die except the slots formed on the first contacting pads; a second die with a second contacting pad attached to the elastic adhesive layer; and a second wire electrically connected the pad and the second contacting pad and a layer of protection layer encapsulates the first die, the second die, the pads, the first wire and the second wire.

The present invention provides a method for forming a stacked dice package comprising: providing a substrate with preformed pads; attaching a first die with a first contacting pad to the substrate, wherein an elastic adhesive layer is preformed on the first die; forming an opening in the elastic adhesive layer at the position of the first contacting pad, wherein the elastic adhesive layer covering all top surface of the first die and forming rims at the peripheral edges of the first die except the openings formed on the first contacting pads; wire-bonding the first contacting pad with the pad; attaching a second die with a second contacting pad to the elastic adhesive layer, wherein the second die attaching on the elastic layer without needing applying an adhesive on the backside of the second die and wire-bonding the second contacting pad with the pad.

### BRIEF DESCRIPTION OF THE DRAWINGS

FIG. 1 illustrates a prior art relating to a stacked dice packaging structure.

FIG. 2 illustrates a cross-sectional view of stacked dice packaging structure according to the present invention.

FIG. 3 illustrates a top view of a stacked dice packaging structure according to the present invention.

FIG. 4 illustrates a stage of the process for manufacturing a stacked dice packaging structure according to the present invention.

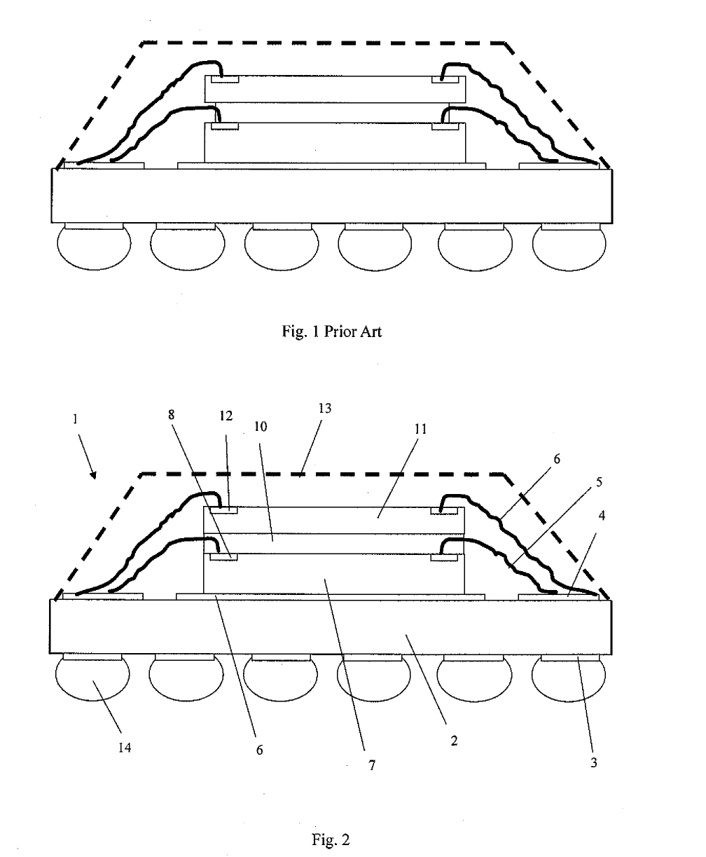

### DESCRIPTION OF THE PREFERRED EMBODIMENT

The invention will now be described in greater detail with preferred embodiments of the invention and illustrations attached. Nevertheless, it should be recognized that the preferred embodiments of the invention is only for illustrating. Besides the preferred embodiment mentioned here, present invention can be practiced in a wide range of other embodiments besides those explicitly described, and the scope of the present invention is expressly not limited expect as specified in the accompanying claims.

The present invention discloses a structure for making a stacked dice packaging structure with elastic adhesive layer. A photosensitive material is coated between the dice and pluralities of openings formed thereon for exposing contacting pads of a die before performing wire-bonding on contacting pads.

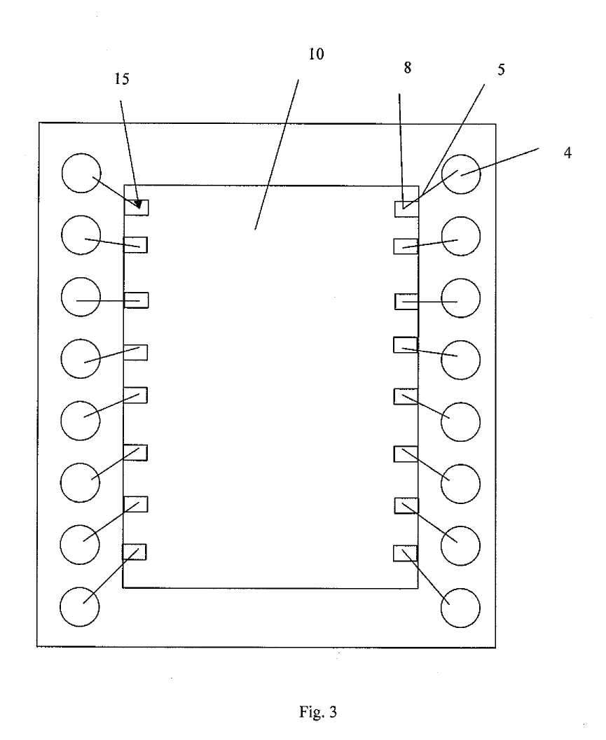

FIG. 2 illustrates a cross-sectional view of a stacked dice packaging structure 1 in accordance with one embodiment of the present invention. As shown in the FIG. 2, the stacked dice packaging structure 1 includes a substrate 2 having pads, which is individually referred to as pad 3 and pad 4, and an adhesive area 6 for placing a first die 7. The substrate 2 is laminated and having an upper surface and a lower surface; wherein the upper surface means the surface on which a die placed. The pad 3 is located on the lower surface of the substrate 2 and a solder ball 14 is formed thereon. The pad 4 is located on the upper surface of the substrate 2 and keeps electrical connection with dice through wires; which is individually referred to as the first wire 5 and the second 6. The material of the substrate includes organic epoxy type FR4, FR5, BT, PCB (print circuit board), alloy or metal. Alternatively, the substrate could be glass, ceramic or silicon.

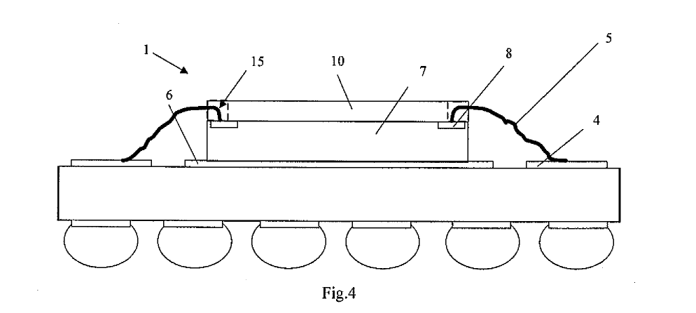

The first die 7 is disposed on the adhesive area 6 of the substrate 2 and fixed by an elastic adhesion layer 10. the first contacting pads (Bonding pads) 8 are formed on the first die 7; i.e., As shown in FIG. 3, the first die 7 has a pluralities of contacting pads 8 located around the periphery of the top surface of the first die 7 for establishing electrical connection between pads 4 and the contacting pads 8. The first wire 5 is made of varieties of metals, such as aluminum or gold.

FIG. 3 shows a top view of the first die with a contacting pads 8 on which a first wires 5 bonds; wherein a layer of photo sensitive elastic material is covered on the top of the first die and a pluralities of slots 15 formed on the peripheral of the elastic adhesive layer 10 and extended to the edges of the die, that is, releasing layer for exposing the contacting pads 8 and receiving the bonding wires coupled between the first die and the substrate, i.e., the elastic adhesive layer 10 covers all to top surface of the first die 7 and forming a rim at the peripheral edge of the first die excepting the slots 15 formed on the pads 8.

The elastic adhesive layer 10 is a material with elongation rate higher than 20%. The preferably thickness of the elastic adhesive layer 10 is more than 20 μm. Preferably, the curing temperature of the elastic adhesive layer 10 is lower than 200° C.

Referring back to FIG. 2, the second die 11 with the second contacting pads 12 is disposed on the elastic adhesive layer 10; wherein the contacting pads 12 keep electrical connection with the pads 4 through the second wire 6. The contacting pad 12 and the second wire 6 are to be understand as being represented pluralities of contacting pads and wires; i.e., the second die 11 has pluralities of contacting pads 12 located around the periphery of the top surface of the second die 11 for keeping electrical contact between the second die 11 and the pads 4 through the second wire 6. The second wire 6 is made of varieties of metals, such as aluminum or gold. In a preferred embodiment of the present invention, the thickness of the elastic adhesive layer 10 is thick enough to make the second die 11 far above the first wire 5 to prevent the second die 11 to contacting the first wire 5. In a preferred embodiment of the present invention, the thickness of the elastic adhesive layer 10 is over the loop height of first wire 5. In a preferred embodiment of the present invention, the second die 11 is placed on the elastic adhesive layer 10 without pre-formed tape on its back side.

As shown in FIG. 2, protection layer 13 encapsulates the first dice 7, the second die 11, the pads 4, the first wire 5 and the second wire 6 to protect them from outside interference, for example, moisture. In one embodiment of the present invention, materials for the protective layer 13 comprise organic compound, liquid compound, and silicone rubber. In another embodiment of the invention, the protection layer 13 preferably has suitable coefficient of thermal expansion to reduce the effects caused by the difference in the thermal coefficient of expansion between the protection layer and the other elements of stacked dice packaging structure. In one embodiment of the invention, the material of the protection layer can be thermoplastics, epoxy.

The process of present invention for manufacturing a stacked dice packaging structure includes providing a wafer with an elastic adhesive layer 10 spin coated on its surface. Then, the wafer is diced into UV tape form or blue tape form; therefore the elastic adhesive layer covering all top surface of said first die and forming rims at the peripheral edges of the first die, A pick and place fine alignment system is used to re-distribute the known good dies, that is, the first die 7 illustrated in FIG. 2, on the substrate 2 with the first contacting pads, which is individually referred to as the pad 3 and the pad 4, and a layer of adhesion 6 is preformed thereon to bond the back side of the first die 7 for forming the structure 1 illustrated in FIG. 4. As shown in FIG. 3, the elastic adhesive layer 10 covers all top surface of first die 7. In a preferred embodiment of the present invention, the applied thickness of the elastic adhesive layer 10 should be thick enough to position the other die, that is, the second die 11 shown in FIG. 2, far above the first wire 5 to prevent the second die 11 to contact the first wire 5.

Next, as shown in FIG. 3, lithography is performed on the elastic adhesive layer 10 for forming openings 15 on the contacting pads 8; openings 15 can be any kind of format that allow the first wire 5 to be wire bonded the first contacting pads 8 and pads 4 of substrate; in the preferred embodiment of the present invention, the openings 15 are rectangular. Pluralities of openings 15 formed on the peripheral of the elastic adhesive layer 10 for exposing the first contacting pads 8, i.e., the elastic adhesive layer 10 covers all to top surface of first die and forming a rim at the peripheral edge of the first die except the openings 15 formed on the first contacting pads 8.

Next, as shown in FIG. 4, wire-bonding the contacting pads 8 of the first die 7 with pads 4 on the substrate 2 by the first wires 5 to establish electrical connection between the first die 7 and the pads 4. In one embodiment of the invention, wire-bonding is performed by conventional technique such as ultrasonic bonding, compression bonding, soldering.

Then pick and place fine alignment system (die bonder) is used again to stack the other known good dies, that is, the second die 11 shown in FIG. 2, on the elastic adhesive layer 10 by attaching for forming a stacked structure of dice; wherein, the second die 11 has pluralities of contacting pads 12 on its top surface; i.e., the second die 11 has pluralities of contacting pads 12 located around the periphery of the top surface of the second die 11. In a preferred embodiment of the present invention, the die 11 is placed on the elastic adhesive layer 10 without needing applying a layer of adhesive on its back side.

Referring to FIG. 2, after the second die 10 is placed on the elastic adhesive layer 10, pluralities of wires represent by the second wire 5 wire-bonding the contacting pads 12 with pluralities of pads 4; wherein, the elastic layer 10 is stable enough for ensuring coplanar of dice when performing wire-bonding on the upper chip and thick enough for preventing the first die 7 and the second die 11 from colliding with each other while performing wire-bonding. In one embodiment of the invention, wire-bonding is performed by conventional technique such as ultrasonic bonding, compression bonding, soldering.

After the second die 11 bonded on the adhesion layer 10, curing the elastic adhesion layer 10 for fixing the shape of the elastic layer. After the dice the substrate is molded by the molding compound, the stacked dice packaging structure is finished. In one embodiment of the present invention, molding is performed by applying a protection layer on the first die 7, second die 11, pluralities of wires represent by the second wire 5 and the first wire 6, a pluralities of pads represent by pad 4 to encapsulating them.

Although preferred embodiments of the present invention have been described, it will be understood by those skilled in the art that the present invention should not be limited to the described preferred embodiments. Rather, various changes and modifications can be made within the spirit and scope of the present invention, as defined by the following claims.

Having described the invention, the following is claimed:

1. A structure of stacked dice package, comprising:
a substrate with pluralities of pads;
a first die with a first contacting pad attached on said substrate;
a first wire electrically connected said pad and said first contacting pad;
an elastic adhesive layer applied on said first die, wherein said elastic adhesive layer having slots formed therein and covering top surface of said first die and forming rims at the peripheral edges of the first die except said slots formed on said first contacting pads;
a second die with a second contacting pad placed on said elastic adhesive layer;
a second wire electrically connected said pad and said second contacting pad; and
a protection layer encapsulates said first die, said second die, said pads, said first wire and said second wire and a portion of said substrate.

2. The structure of claim 1, wherein the elongation rate of said elastic adhesive layer is higher than 20%.

3. The structure of claim 1, wherein the thickness of said elastic adhesive layer is over the loop height of said first wire.

4. The structure of claim 1, wherein the curing temperature of said elastic adhesive layer is lower than 200° C.

5. A method for forming a stacked dice package comprising:
providing a substrate with preformed pads;
attaching a first die with a first contacting pad to said substrate, wherein an elastic adhesive layer is preformed on said first die, wherein said elastic adhesive layer covering top surface of said first die and forming rims at the peripheral edges of the first die;
forming slots in said elastic adhesive layer at the position over said first contacting pad, wherein said elastic adhesive layer covering top surface of said first die and forming rims at the peripheral edges of the first die except said slots formed on said first contacting pads;
wire-bonding said first contacting pad with said pad;
attaching a second die with a second contacting pad to said elastic adhesive layer, wherein said second die attaching on said elastic layer without needing applying an adhesive on the backside of said second die; and
wire-bonding said second contacting pad with said pad.

6. The method of claim 5, wherein said opening is formed by lithography.

7. The method of claim 5, wherein said elastic adhesive layer is applied on said first die by coating.

8. The method of claim 5, wherein the elongation rate of said elastic adhesive layer is higher than 20%.

9. The method of claim 5, wherein the thickness of said elastic adhesive layer is over the loop height of the first wire.

10. The method of claim 5, wherein the curing temperature of said elastic adhesive layer is lower than 200° C.
